(19) United States
(12) Patent Application Publication
(10) Pub. No.: US 2024/0313732 A1
(43) Pub. Date: Sep. 19, 2024

(54) AMPLIFIERS

(71) Applicant: Nordic Semiconductor ASA, Trondheim (NO)

(72) Inventors: Marko PESSA, Oulu (FI); David ZAPATA, Oulu (FI)

(73) Assignee: Nordic Semiconductor ASA, Trondheim (NO)

(21) Appl. No.: 18/601,676

(22) Filed: Mar. 11, 2024

(30) Foreign Application Priority Data
Mar. 14, 2023 (GB) 2303730.2

(51) Int. Cl. H03G 3/30; H03F 3/21

(52) U.S. Cl. CPC H03G 3/3036; H03F 3/211; H03F 2200/451; H03G 2201/103; H03G 2201/307

(57) ABSTRACT

An amplifier circuit portion is proved. The amplifier circuit is arranged to amplify an input signal with a gain based on a gain control signal. The amplifier circuit portion comprises a plurality of amplifier cells having a common input for receiving the input signal and a common output for providing an amplified version of the input signal. At least one of the amplifier cells is operable in: a controllable gain mode in which the amplifier cell provides an amplification gain to the input signal based on the gain control signal; and a fixed gain mode in which the amplifier cell provides a fixed, non-zero amplification gain to the input signal.

### CROSS REFERENCE TO RELATED APPLICATION

This application claims priority from Great Britain Application No. 2303730.2, filed Mar. 14, 2023, which application is incorporated herein by reference in its entirety.

### BACKGROUND OF THE INVENTION

The present invention relates to amplifier circuit portions.

The amplification of electrical signals has many different useful applications. For instance, radio transmitters typically operate by modulating a carrier signal to encode some data, and then amplifying and broadcasting the signal as radio waves using one or more antennas. The radio signal can then be detected and demodulated by a radio receiver to recover the encoded data.

The distance at which a receiver can successfully recover the encoded data depends somewhat on the power with which the signal is transmitted by the transmitter. In general, high transmitter power outputs enable longer range communications. The transmission power in turn depends in part on a gain provided by a power amplifier in the transmitter.

It is often desirable to control accurately the transmission power of a radio transmitter. For instance, in many countries transmitter power outputs are tightly regulated, with strict power limits in certain frequency bands. Accurate control allows transmission power to be set as close as possible to the regulatory maximums. It may also be beneficial to accurately control the power used by a transmitter device with limited energy resources, e.g. to minimise power variation and maximise battery life. It is also generally desirable to control accurately the gain of an amplifier in other contexts.

In some implementations, a gain control signal can be used to control the gain provided by an amplifier. In such cases, the precision with which the gain can be controlled depends on the precision of the gain control signal. For instance, an 8-bit digital gain control signal may be used to select one of 256 different possible gain levels. For amplifiers capable of delivering a wide range of gains, a very high resolution control signal may be needed to provide sufficiently precise control over the whole range. An improved approach may be desired.

### SUMMARY OF THE INVENTION

According to a first aspect of the present invention there is provided an amplifier circuit portion arranged to amplify an input signal with a gain based on a gain control signal, the amplifier circuit portion comprising a plurality of amplifier cells having a common input for receiving the input signal and a common output for providing an amplified version of the input signal;
wherein at least one of the amplifier cells is operable in:
   a controllable gain mode in which the amplifier cell provides an amplification gain to the input signal based on the gain control signal; and
   a fixed gain mode in which the amplifier cell provides a fixed, non-zero amplification gain to the input signal.

Thus, it will be appreciated by those skilled in the art that, because the at least one amplifier cell can be operated in different modes, the gain profile of the amplifier circuit portion (i.e. how the gain varies with gain control signal) can be tailored more optimally to different situations and implementations. The amplifier cells have a common input and a common output (i.e. they are connected in parallel), so the overall gain profile of the amplifier circuit portion depends on the way each of the amplifier cells operates. By operating amplifier cell(s) in appropriate mode(s), a gain control signal may be used to control more precisely the gain provided by the amplifier. Useful optimisation may be achieved even when only one amplifier cell is operable in the controllable gain mode and the fixed gain mode. Other amplifier cells of the plurality may be operable in only the controllable gain mode or in only the fixed gain mode. However, in a set of embodiments, multiple amplifier cells are operable in the controllable gain mode and the fixed gain mode. This may facilitate further optimisation of the gain profile of the amplifier circuit portion.

An amplifier cell operating in the fixed gain mode provides a fixed amplification gain to the input signal and is therefore not sensitive to changes in the gain control signal. As such, the minimum total (non-zero) gain deliverable by the amplifier circuit portion is determined at least partially by amplifier cells that are operating in the fixed gain mode. In a set of embodiments, the amplifier circuit portion is operable in a plurality of different minimum gain configurations in which different combinations of amplifier cells operate in the fixed gain mode. For instance, in some implementations it may be unnecessary for the amplifier to be able to deliver less than a minimum required gain (e.g. when a desired transmission power of a radio transmitter using the amplifier circuit portion always requires a certain amplifier gain in all expected environmental conditions). In such implementations, the amplifier circuit portion may be operated in a minimum gain configuration corresponding to the minimum required gain. Setting a minimum gain using an appropriate configuration reduces the range of gains deliverable by the amplifier circuit portion, so that a gain control signal with a given resolution can control the gain provided by the amplifier circuit portion with improved precision.

For example, a 4-bit digital gain control signal may be able to control the amplifier circuit portion to deliver 16 different gains. When the gain deliverable by the amplifier circuit portion ranges between 0 dB and 10 dB, the 4-bit gain control signal may be able to specify a gain to a precision of roughly 0.6 dB (10 dB/16 levels). However, if the minimum gain deliverable is increased to 2 dB by operating one or more amplifier cells in the fixed gain mode, the same 4-bit gain control signal can provide gain control precision of 0.5 dB (8 dB/16 levels). In other situations, other combinations of amplifier cells (e.g. a larger number of cells and/or larger cells) may be operated in the fixed gain mode to further increase the minimum gain deliverable by the amplifier circuit portion (and to further increase the precision with which a gain control signal having with a given resolution can control the amplifier gain).

In a set of embodiments, at least one of the amplifier cells is operable in a disabled mode in which the amplifier cell does not provide any amplification gain to the input signal. It will however be recognised that it is not essential in such embodiments for one or more of the amplifier cells to actually operate in the disabled mode at all times. At some times all of the amplifier cells may be enabled, even if one, some or all of them can be operated in the disabled mode at other times.

Amplifier cells that operate in the disabled mode provide no amplification gain to the input signal and are not sensitive to changes in the gain control signal. As such, the maximum gain deliverable by the amplifier circuit portion is determined at least partially by the number and properties of amplifier cells that are operating in the disabled mode. In other words, a maximum gain deliverable by the amplifier circuit portion may be reduced by disabling one or more amplifier cells. In a set of embodiments, the amplifier circuit portion is operable in a plurality of different maximum gain configurations in which different combinations of amplifier cells operate in the disabled mode. In some implementations it may be unnecessary for the amplifier to be able to deliver more than a maximum required gain (e.g. corresponding to transmission power limit for a radio transmitter using the amplifier circuit portion). In such implementations, the amplifier circuit portion may be operated in a maximum gain configuration corresponding to the maximum required gain. As with a minimum gain, setting a maximum gain using an appropriate configuration of amplifier cells reduces the range of gains deliverable by the amplifier circuit portion, so that a gain control signal with a given resolution can control the gain provided by the amplifier circuit portion with improved precision.

At least one of the amplifier cells may be operable in the controllable gain mode and the disabled mode. At least one of the amplifier cells may be operable in the fixed gain mode and the disabled mode. In some embodiments, at least one of the amplifier cells is operable in the controllable gain mode, the fixed gain mode and the disabled mode. In some embodiments all of the amplifier cells are operable in at least one of the controllable gain mode, the fixed gain mode or the disabled mode (i.e. these are the only modes of operation available). In some embodiments all of the amplifier cells are operable in the controllable gain mode, the fixed gain mode and the disabled mode.

When viewed in a slightly different way, it may be recognised that the relative quantity (in number and/or size) of amplifier cells operating in the controllable gain mode, the fixed gain mode and optionally the disabled mode may determine a sensitivity of the gain provided by the amplifier circuit portion to changes in the gain control signal. For instance, if all of the amplifier cells are operated in the controllable gain mode, a given change in gain control signal may lead to a large change in gain. However, if only a small proportion of amplifier cells operate in the controllable gain mode compared to those operating in the fixed gain mode and/or the disabled mode, the same change in gain control signal may lead to a much smaller change in gain. Thus, in some embodiments the amplifier circuit portion is operable to have a plurality of different sensitivity configurations in which different combinations of amplifier cells operate in the controllable gain mode and the fixed gain mode and optionally the disabled mode. It will be appreciated that in many implementations selecting a sensitivity configuration may be functionally equivalent to selecting minimum and/or maximum deliverable gains for the amplifier circuit portion (because these correspond to minimum and maximum values of the gain control signal which is related to the actual gain produced by the sensitivity of the amplifier circuit portion).

The amplifier circuit portion may be in one of the minimum gain configurations and one of the maximum gain configurations. In other words, the amplifier circuit portion may be configured to have a minimum and a maximum deliverable gain by operating amplifier cell(s) in appropriate mode(s). The deliverable range of gains (between the minimum and the maximum) may be selected to correspond to a range of gains required for a particular implementation. It may be desirable to match the range of gains that can be delivered by the amplifier circuit portion as closely as possible to a range of gains required for a particular implementation in order to maximise the precision with which a gain control signal having a given resolution can control the gain.

In a set of embodiments, one or more of the amplifier cells comprises a gain transistor and a switch transistor connected in series between a voltage rail (e.g. ground) and the common output. The gain and/or switch transistors may comprise field-effect transistors (e.g. nMOSFETs). A drain of the gain transistor may be connected to the common output. A source of the switch transistor may be connected to the voltage rail. A source of the gain transistor may be connected to a drain of the switch transistor. A gate of the gain transistor may be connected to the common input.

In some embodiments, the operation of the amplifier cell may be controlled by controlling a gate voltage of the switch transistor. In such embodiments, the switch transistor may be considered as a variable resistor. When a gate voltage of the switch transistor is high, its effective resistance is low and the gain provided by the gain transistor is high. When a gate voltage of the switch transistor is low, its effective resistance is high and the gain provided by the gain transistor is low.

An amplifier cell may be operated in the disabled mode by connecting the gate of its switch transistor to less than a threshold voltage (e.g. at or below ground). An amplifier cell may be operated in the fixed gain mode by fixing the gate voltage of its switch transistor to a fixed voltage above the threshold voltage. An amplifier cell may be operated in the controllable gain mode by varying the gate voltage of its switch transistor according to the gain control signal (e.g. equal to or in proportion to a value of the gain control signal).

In a set of embodiments, a configuration of the amplifier circuit portion is based on one or more configuration signals. One or more configuration signals may specify a minimum gain configuration and/or a maximum gain configuration in which to operate the amplifier circuit portion.

In a set of embodiments, one or more configuration signals control directly a mode in which one or more amplifier cells operates. The configuration signal(s) may control directly the mode of amplifier cell(s) to achieve a minimum gain configuration and/or maximum gain configuration of the amplifier circuit portion. For instance, the amplifier circuit portion may be arranged to receive a configuration signal for each of the amplifier cells that specifies which mode the amplifier cell operates in.

Each amplifier cell may be arranged to receive an enable signal. An amplifier cell may be controlled to operate in the disabled mode by setting its enable signal to a first value (e.g. logic high). In other modes the enable signal may be at a second value (e.g. logic low). Each amplifier cell may be arranged to receive a respective control enable signal. An amplifier cell (that is not being operated in the disabled mode) may be controlled to operate in the fixed gain mode by setting its control enable signal equal to a first value (e.g. ground). An amplifier cell (that is not being operated in the disabled mode) may be operated in the controllable gain mode by setting its control enable signal equal to a second value (e.g. logic high).

In a set of embodiments, each amplifier cell may comprise an inverter. The inverter may have an input connected to the enable signal (which determines if the cell operates in the disabled mode or in an enabled mode). The inverter may have an output connected to the gate of the switch transistor. The inverter may generate a voltage at the output that corresponds to a logical inverse of a voltage at the input. The states at the input and the output may be indicated with different voltages. The inverter may have a supply voltage that determines a voltage of a logic high at the output. The inverter may have a selectable supply voltage. The supply voltage may be selected to be a fixed voltage or a variable voltage that is based on the gain control signal. The selection of the supply voltage to be variable or fixed may be controlled by the control enable signal for that amplifier cell (i.e. by acting as a supply control signal). For instance, if the control enable signal has the first value (e.g. logic high) the supply voltage may be fixed, and if the control enable signal has the second value (e.g. logic low) the supply voltage may be variable.

It will be appreciated that, in such embodiments, when the amplifier cell is enabled (e.g. when the enable signal is logic low), the control enable signal determines whether the amplifier cell operates in the fixed gain mode or the controllable gain mode. If the control enable signal controls the supply voltage to be fixed, a logic low enable signal is passed through the inverter to produce a logic high at the output with a fixed voltage set by the supply voltage and the amplifier cell operates in the fixed gain mode. When the control enable signal controls the supply voltage to be variable, a logic low enable signal is passed through the inverter to produce a logic high at the output with a variable voltage that is based on the gain control signal and the amplifier cell operates in the controllable gain mode. If the enable signal is logic high, this is inverted such that the gate voltage of the switch transistor is always below the threshold and the amplifier cell operates in the disabled mode regardless of the value of the control enable signal.

The common output of the amplifier cells may comprise an output of the amplifier portion (i.e. there may be no further components between the common output and the output of the amplifier portion). However, in a set of embodiments the amplifier circuit portion comprises an output stage with an input connected to the common output of the amplifier cells and an output that is an output of the amplifier circuit portion. The output stage may comprise a cascode stage. The amplifier circuit portion may comprise a cascode amplifier, with the amplifier cells forming a common-source amplifier and the output stage forming a common-gate amplifier. The output stage may comprise a cascode transistor. A source of the cascode transistor may be connected to the common output of the amplifier cells. A drain of the cascode transistor may be connected to an output of the amplifier circuit portion. A gate of the cascode transistor may be connected to a cascode voltage. The cascode voltage may be a fixed value, or it may be set to different values for different configurations.

Every amplifier cell in the amplifier circuit portion may be operable in the disabled, fixed gain and controllable gain modes. However, in some implementations it may not be necessary for all amplifier cells to be operable in all three modes. In a set of embodiments, the amplifier circuit portion comprises one or more further amplifier cells. The amplifier cells may be operable in only the controllable gain mode or only the fixed gain mode. The amplifier cells may be operable in only the controllable gain mode or the disabled mode, or only the fixed gain mode or the disabled mode.

In some embodiments, the amplifier cells are all equally sized (e.g. with equal transconductance). In such embodiments, minimum/maximum gain configurations may simply comprise appropriate numbers of amplifier cells operating in the different modes. However, in some embodiments two or more of the amplifier cells may have different sizes (e.g. different transconductances). In such cases minimum/maximum gain configurations may comprise combinations of specific amplifier cells operating in different modes.

In some embodiments, the amplifier circuit portion comprises one or more amplifier slices comprising a set of amplifier cells. Each amplifier slice may share a common enable signal. A whole slice of amplifier cells may thus be enabled or disabled by a single enable signal for that slice. This may simplify the configuration of the amplifier circuit portion, especially if the amplifier circuit portion comprises a large number of amplifier cells. In some embodiments the amplifier circuit portion comprises a plurality of amplifier slices. Two or more amplifier slices may have different total sizes (i.e. a total of the sizes of its constituent amplifier cells). The amplifier slices may be sized and ordered such that successive disabling of amplifier slices in said order leads to an approximately linear decrease in maximum gain deliverable by the amplifier circuit portion (e.g. a linear decrease when gain is measured in logarithmic units (dB) or in standard units). In a set of embodiments, a largest amplifier slice of the amplifier circuit portion comprises one or more amplifier cells operable in the fixed gain mode and the controllable gain modes and optionally also in the disabled mode.

A value indicated by the gain control signal may indicate a gain to be provided by the amplifier circuit portion. The gain control signal may comprise an analogue signal, such that a voltage of the gain control signal indicates a gain to be provided by the amplifier circuit portion. The voltage of an analogue gain control signal may be used to control directly the amplifier cells (e.g. the gate voltage of a switch transistor in the amplifier cell may be equal to or derived from the analogue gain control signal). Alternatively, the gain control signal comprises a digital signal in which a value indicating a gain to be provided is encoded. The amplifier circuit portion may comprise a digital-to-analogue converter (DAC) arranged to convert a digital gain control signal into an analogue gain control signal (e.g. that can be used to control the amplifier cells). Alternatively, a DAC may be provided separately so that a digital gain control signal is converted elsewhere into an analogue gain control signal received by the amplifier circuit portion.

Optimising amplifier control may be useful in many amplifier implementations. The input signal may be any electrical signal that requires amplification. However, the present invention may be particularly suited to radio transmission implementations. In a set of embodiments, the input signal is a radio frequency signal (e.g. having a frequency between 20 KHz and 300 GHz). The input signal may be a microwave frequency signal (e.g. having a frequency of over 1 GHz). The input signal may have a frequency of approximately 2.4 GHz. For instance, the input signal may be compatible with a Bluetooth communication standard.

The amplifier circuit portion may be provided as part of a dedicated amplifier device. However, in practice amplifier circuit portions are often incorporated into other devices that provide more than mere amplification. In a set of embodiments, the amplifier circuit portion comprises a power amplifier for a radio transmitter device.

According to a second aspect of the present invention there is provided a device comprising a control circuit portion and an amplifier circuit portion as described herein. The control circuit portion may comprise a microprocessor. In a set of embodiments the control circuit portion comprises a System-on-Chip (SoC).

The control circuit portion may be arranged to generate the gain control signal that controls the gain provided by the amplifier circuit portion. The control circuit portion may be arranged to generate an analogue gain control signal that may be used directly to control amplifier cells of the amplifier circuit portion. However in a set of embodiments the control circuit portion is arranged to generate a digital gain control signal and the device also comprises a digital-to-analogue converter (DAC) arranged to convert the digital gain control signal into an analogue gain control signal and to provide the analogue gain control signal to the amplifier circuit.

In relevant embodiments, the control circuit portion may be arranged to provide the one or more configuration signals to the amplifier circuit portion. In other words, the control circuit portion may be arranged to configure the amplifier circuit portion (e.g. into a desired maximum gain and/or minimum gain configuration). The control circuit portion may store information relating to maximum gain and/or minimum gain configurations. For instance, the control circuit portion may store information identifying the configuration signal(s) required to put the amplifier circuit portion into a desired maximum gain and/or minimum gain configuration. The information stored by the control circuit portion may be calibrated for the specific amplifier circuit portion used. For instance, the gain response of each of the amplifier cells may be measured (e.g. during manufacture) to determine combinations of amplifier cell modes needed to realise different maximum gains and/or minimum gains (e.g. to determine amplifier cells or slices that should be disabled to achieve different maximum gains). These combinations may then be stored to the control circuit portion. The control circuit portion can then retrieve and use this information during use to configure the amplifier circuit portion appropriately. Calibrating the amplifier circuit portion in advance in this way may compensate for process variations in components of the amplifier circuit portion.

The device may be a radio transmitter device arranged to transmit the amplified version of the input signal provided by the amplifier circuit portion as a radio signal.

The radio transmitter device may be arranged to sense a transmission power of the transmitted radio signal. For instance, the radio transmitter device may comprise a sensor arranged to sense a power of the amplified version of the input signal. The sensor may be arranged to sample the amplified version of the input signal and convert this sample into a DC voltage proportional to the power of the amplified signal. The sensor may be arranged to produce a transmission power feedback signal indicating a power of the transmitted radio signal. The transmission power feedback signal may comprise the DC voltage proportional to the power of the amplified signal.

The control circuit portion may be arranged to generate the gain control signal based on a sensed transmission power (e.g. based on the transmission power feedback signal). The control circuit portion may control the gain control signal so as to maintain a transmission power at, above or below a desired power level (e.g. below a regulatory transmission power limit). For example, if the control circuit portion senses that the transmission power is increasing, it may reduce the value of a gain control signal to reduce a gain provided by the amplifier circuit portion and thus counteract the sensed increase in the transmission power.

The control circuit portion may be arranged to provide the input signal to the amplifier circuit portion. Alternatively, a separate circuit portion or an entirely separate device may provide the input signal (e.g. the device may be a radio transmitter front-end device arranged to handle amplification and transmission of the input signal).

In embodiments where the device is a radio transmitter device, the control circuit portion may be arranged to determine a maximum gain and/or a minimum gain configuration in which to operate the amplifier circuit portion based on one or more of: a transmission power, a transmission power limit (e.g. a regulatory limit), current operating conditions (e.g. temperature, humidity, frequency, supply voltage), expected future operating conditions and an expected variation in operating conditions. For instance, the control circuit portion may determine that the temperature is likely to vary by 2° C. over the period of operation of the radio transmitter device and configure the minimum and maximum gains of the amplifier device to be respectively as high and as low as possible whilst still allowing the device to maintain a target transmission power through the expected temperature variation.

Features of any aspect or embodiment described herein may, wherever appropriate, be applied to any other aspect or embodiment described herein. Where reference is made to different embodiments, it should be understood that these are not necessarily distinct but may overlap.

### BRIEF DESCRIPTION OF THE DRAWINGS

One or more non-limiting examples will now be described, by way of example only, and with reference to the accompanying figures in which:

FIG. 1 is a schematic view of a transmitter device according to an embodiment of the invention;

FIG. 2 is a schematic view of a power amplifier of the transmitter device;

FIG. 3 is a graph illustrating the maximum transmission power of the power amplifier in various configurations; and

FIG. 4 is a graph illustrating the controllable range of transmission power of the power amplifier in various configurations.

### DETAILED DESCRIPTION

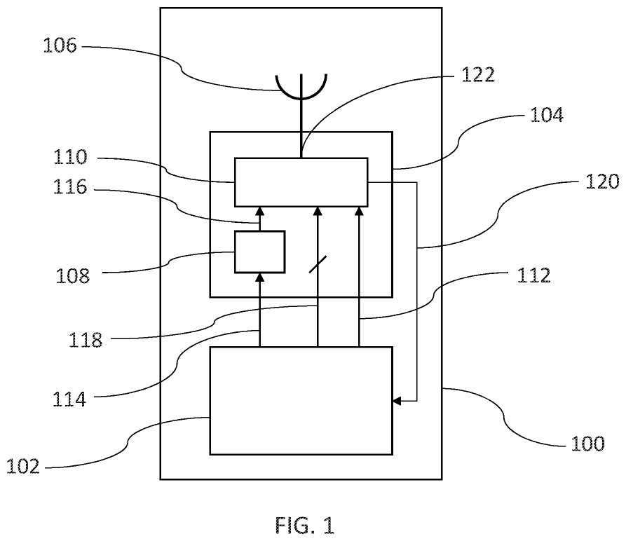

FIG. 1 shows a transmitter device 100 comprising a System on Chip (SoC) 102, an RF front-end portion 104 and an antenna 106. The front-end portion 104 comprises a digital-to-analogue converter (DAC) 108 and a power amplifier 110.

In use, the SoC 102 generates radio frequency electrical signals 112 (e.g. in which data to be transmitted is encoded) and sends these to the front-end portion 104 along with a digital gain control signal 114 and a set of digital configuration signals 118 for configuring the power amplifier 110. The configuration signals 118 include fourteen slice enable signals and eight control enable signals, discussed in more detail below. Once the power amplifier 110 is configured appropriately, the SoC 102 uses the digital gain control signal 114 to control precisely a gain that the power amplifier 110 applies when amplifying the signals 112. An output 122 of the power amplifier 110 outputs an amplified version of the electrical signals 112 to the antenna 106 for transmission.

The SoC 102 receives a transmission power feedback signal 120 from the power amplifier 110. The transmission power feedback signal 120 indicates a transmission power with which the signals 112 are being transmitted. The transmission power with which the signals 112 are transmitted may vary during use, e.g. due to changing environmental conditions such as temperature. The SoC 102 continually adjusts the digital gain control signal 114 (and potentially one or more of the digital configuration signals 118) based on the feedback signal 120 to keep the transmission power of the transmitter device 110 below, but as close as possible to, a regulatory transmission power limit.

The operation of the front-end portion 104 will now be described in more detail.

The DAC 108 receives the digital gain control signal 114 and produces an analogue gain control signal 116 based on the value indicated by the digital gain control signal 114. The analogue gain control signal 116 is a voltage ranging between a minimum gain control voltage close to ground (e.g. 0.7 V) and a maximum gain control voltage close to the maximum voltage tolerated by the switch transistor (e.g. 1.6V) The precision with which the gain can be adjusted is determined by the precision with which the DAC 108 can adjust the analogue gain control signal 116 (i.e. the resolution of the DAC 108).

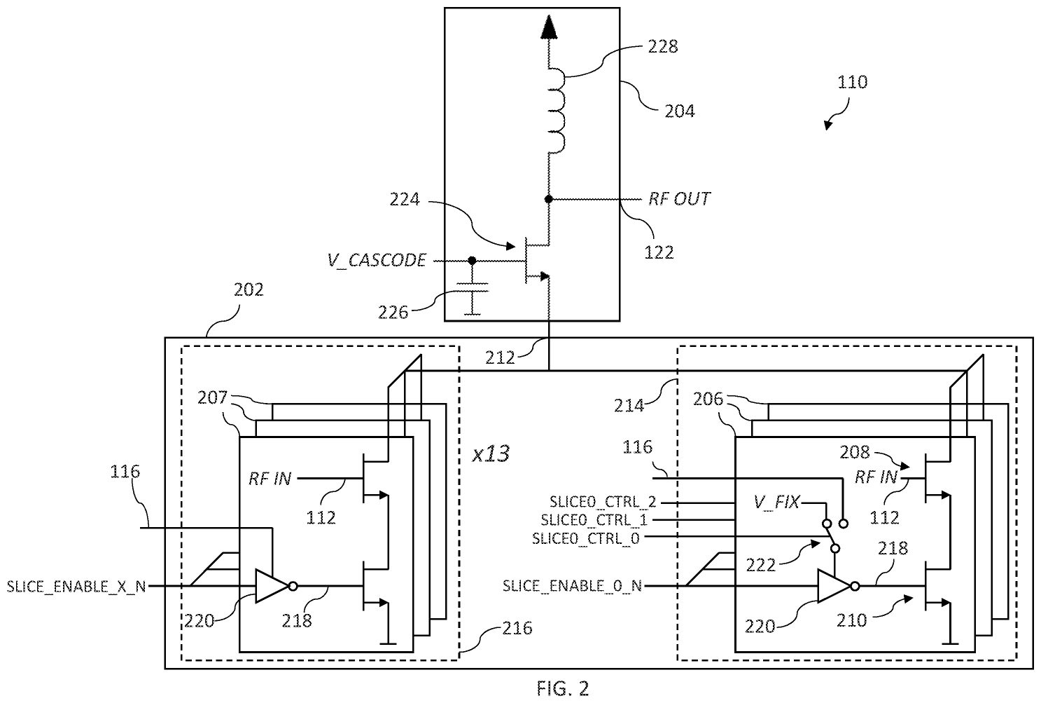

The power amplifier 110 is shown in more detail in FIG. 2. The power amplifier 110 comprises an input stage 202 which receives the electrical signal 112 (RF IN) from the SoC 102 and an output cascode stage 204 having the output 122 which outputs the electrical signal 112 after amplification (RF OUT). The input stage 202 comprises a first amplifier slice 214 and thirteen second amplifier slices 216 (only one second amplifier slice 216 is shown in FIG. 2 for ease of illustration). The first amplifier slice 214 features eight first amplifier cells 206 and each second amplifier slice 216 features eight second amplifier cells 207 (only three cells of each type are shown in FIG. 2 for ease of illustration).

Each of the amplifier slices 214, 216 is operable to amplify the input electrical signal 112. Each amplifier slice 214, 216 has a different total size (i.e. total transconductance). The first amplifier slice 214 is the biggest.

Each of the amplifier cells 206, 207 comprises a gain transistor 208 and a switch transistor 210 connected in series. The source of each switch transistor 210 is connected to ground, and the drain of each gain transistor 208 is connected to a common output 212 of the input stage 202 (i.e. the amplifier cells 206, 207 are connected in parallel). The gate of each gain transistor 208 is connected to the radio frequency electrical signals 112 from the SoC 102 (RF IN). The gate of each switch transistor 210 is connected to a respective cell enable signal 218. Under the control of the cell enable signal 218 as a gate voltage, the switch transistor 210 acts as an adjustable resistor and thus controls the gain provided to the RF signal 112 by the amplifier cell 206, 207. When the cell enable signal 218 is high (e.g. at a logic high voltage), the effective resistance of the switch transistor 210 is low and the gain provided by the gain transistor 208 is high. When the cell enable signal 218 is at 0 V (i.e. at a logic low voltage), the gain provided by the gain transistor 208 is effectively zero. When the cell enable signal 218 is below the maximum logic high voltage (i.e. less than 1.6 V), an intermediate level of gain is provided by the gain transistor 208.

Each of the amplifier cells 206, 207 also comprises an inverter 220. The inverter 220 has an input connected to a slice-specific negative enable signal

SLICE_ENABLE_X_N (from the SoC 102 as one of the configuration signals 118). Each amplifier cell 206, 207 in a given slice receives the same negative enable signal SLICE_ENABLE_X_N. For instance, the amplifier cells 206 of the first amplifier slice 214 all receive the SLICE_ENABLE_0_N negative enable signal.

The inverter 220 has an output connected to the gate of the switch transistor 210. The inverter 220 generates a voltage at the output that corresponds to a logical inverse of a voltage at the input. The inverter 220 receives a supply voltage that determines a voltage of a logic high at the output.

In the second amplifier cells 207, the supply voltage of the inverter 220 is the analogue gain control voltage 116. In the first amplifier cells 206, the supply voltage of the inverter 220 comes from a switching arrangement 222. The switching arrangement 222 provides either the analogue gain control voltage 116 or a fixed voltage V_FIX as the supply voltage of the inverter. In this embodiment the fixed voltage V_FIX is set to 1.6 V. The switching arrangement 222 of a given amplifier cell 206 is controlled by a cell-specific control enable signal. Control enable signals SLICE0_CTRL_0, SLICE0_CTRL_1, SLICE0_CTRL_2 are illustrated in FIG. 2 for each of the three amplifier cells 206 shown. The cell-specific control enable signals are provided by the SoC 102 as part of the configuration signals 118.

The output cascode stage 204 comprises a cascode transistor 224, a capacitor 226 and an inductor 228. The common output 212 of the input stage 202 is connected to the source of the cascode transistor 224. The gate of the cascode transistor 224 is connected to a cascode voltage V_CASCODE in parallel with the capacitor 226. The output 122 is between the drain of the cascode transistor 224 and the inductor 228. The cascode voltage may also be programmable by the SoC 102.

Each amplifier cell 206 of the first amplifier slice 214 can be operated in three different modes: a controllable gain mode, a fixed gain mode and a disabled mode.

In a controllable gain mode the amplifier cell 206 provides an amplification gain to the input signal 112 that is based on the analogue gain control voltage 116. The SoC 102 configures an amplifier cell 206 to operate in this mode by providing a logic low negative enable signal (i.e. SLICE_ENABLE_0_N) and a logic high control enable signal (e.g. SLICE0_CTRL_0) to the amplifier cell 206. This results in the cell enable signal 218 (i.e. the gate voltage of the switch transistor 210) having a magnitude equal to that of the gain control voltage 116. The gain transistor 208 of the amplifier cell 206 thus provides an amplification gain to the input signal 112 that is based on the analogue gain control voltage 116.

In the fixed gain mode the amplifier cell 206 provides a fixed, non-zero amplification gain to the input signal 112 that is based on the fixed voltage V_FIX. The SoC 102 configures an amplifier cell 206 to operate in this mode by providing a logic low negative enable signal (i.e. SLICE_ENABLE_0_N) and a logic low control enable signal (e.g. SLICE0_CTRL_0) to the amplifier cell 206. This results in the cell enable signal 218 (i.e. the gate voltage of the switch transistor 210) having a magnitude equal to the fixed voltage V_FIX (1.6 V). The gain transistor 208 of the amplifier cell 206 thus provides maximum amplification gain to the input signal 112.

Finally, in the disabled mode the amplifier cell 206 does not provide any amplification gain to the input signal 112. The SoC 102 configures an amplifier cell 206 to operate in this mode by providing a logic high negative enable signal (i.e. SLICE_ENABLE_0_N) to the amplifier cell 206. This results in the cell enable signal 218 (i.e. the gate voltage of the switch transistor 210) being always below the threshold gate voltage of the switch transistor 210 connected to and the gain transistor 208 providing no amplification gain to the input signal 112.

Because the second amplifier cells 207 do not feature a 222 switching arrangement, they are operable in only the controllable gain and disabled modes.

The SoC 102 uses the configuration signals 118 to configure the power amplifier 110 to have a desired gain performance, by operating different combinations of amplifier cells 206, 207 in different modes. This allows the SoC 110 to maximise a precision with which the gain provided by the power amplifier 110 can be controlled in a range of different operating conditions.

The SoC 102 (or a user of the SoC 102) determines a maximum gain requirement for the current implementation and conditions. For instance, the SoC 102 may determine that a current transmission power limit (e.g. due to local regulations) is 10 dBm. The SoC 102 configures the power amplifier 110 into a maximum gain configuration corresponding to a 10 dBm maximum transmission power by putting the amplifier cells 206, 207 of an appropriate combination of amplifier slices 214, 216 into the disabled mode.

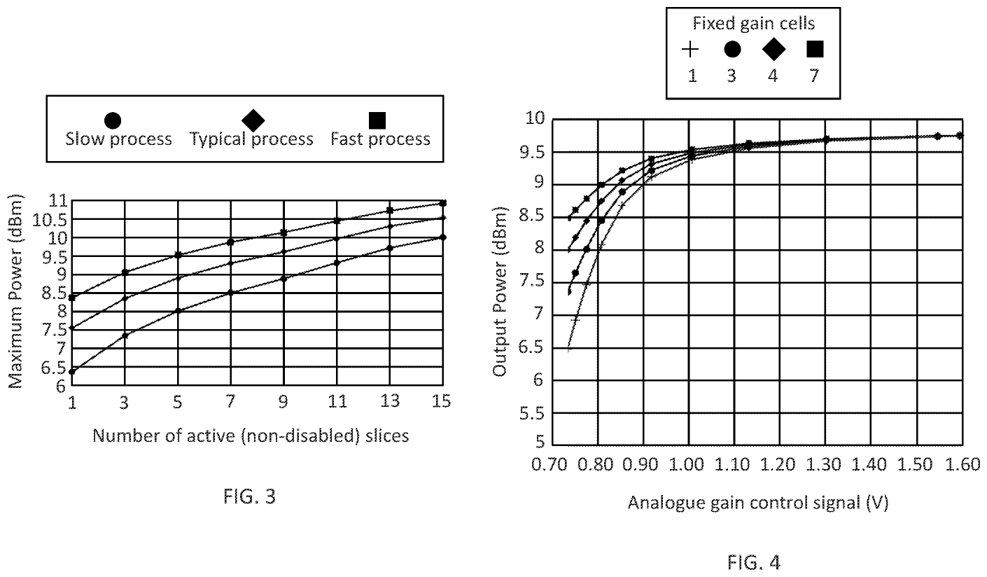

Amplifier cells 206, 207 in the disabled mode do not contribute to the output gain regardless of the value of the digital gain control signal 114, reducing the maximum gain deliverable by the power amplifier 110. FIG. 3 shows the maximum transmission power deliverable by the power amplifier 110 with different numbers of non-disabled amplifier slices 214, 216 (i.e. different maximum gain configurations). The order in which the amplifier slices 214, 216 are disabled may be calibrated to produce a reasonably linear decrease in maximum power (when measured in dBm). In selecting the appropriate maximum gain configuration the SoC 102 takes into account process variations in gain response that are measured during manufacture. FIG. 3 shows how the maximum transmission power response of the power amplifier 110 may change due to process variations. The first amplifier slice 214 is always enabled (i.e. SLICE_ENABLE_0_N is always logic low).

The SoC 102 (or a user of the SoC 102) also determines a minimum gain requirement for the current implementation and conditions. For instance, an expected worst-case variation of environmental conditions may increase power from 10 dBm to 12 dBm, so the gain provided by the power amplifier 110 needs to be controllable within a range of roughly 2 dB below the maximum gain value to bring the power back to 10 dBm and avoid exceeding the transmission power limit.

In other words, a “nominal” transmission power (i.e. a power in nominal environmental conditions) needs to be adjustable down to 8 dBm to avoid exceeding the limit of 10 dBm. The SoC 102 thus also configures the power amplifier 110 into a corresponding minimum gain configuration by putting an appropriate combination of (enabled) amplifier cells 206 into the fixed gain mode.

Amplifier cells 206 in the fixed gain mode provide a fixed amplification gain to the input signal 112 and are not sensitive to changes in the analogue gain control signal 116, thus determining a minimum level of gain deliverable by the power amplifier 110. The remaining enabled amplifier cells 206, 207 are operated in the controllable gain mode.

FIG. 4 shows how operating a greater number of amplifier cells 206 in the fixed gain mode reduces the range of gain (and thus transmission powers) deliverable by the power amplifier 110. It can be seen from FIG. 4 that when seven (out of eight) amplifier cells 206 are operated in the fixed gain mode, the transmission power achievable with an analogue gain control signal 116 between 0.7 V and 1.6 V ranges from roughly 8.25 dBm-9.75 dBm. When viewed in another way, increasing the number of amplifier cells 206 operating in the fixed gain mode decreases the sensitivity of amplifier gain to changes in the gain control signal 114 (i.e. the steepness of the curves shown in FIG. 4 is reduced).

Thus, by configuring the amplifier cells 206, 207 into minimum and maximum gain configurations appropriate to the current operating conditions, a controllable gain range of the amplifier may be minimised. This maximises the precision with which the gain control signal 114 and associated circuitry (e.g. the DAC 108) can control the gain provided by the power amplifier 110. This improved precision improves the level of control that the SoC 102 has over the transmission power of the transmitter device 100. The radio transmitter device 100 can thus advantageously be operated with reduced transmission power variation and closer to a regulatory power limit.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

1. An amplifier circuit portion arranged to amplify an input signal with a gain based on a gain control signal, the amplifier circuit portion comprising a plurality of amplifier cells having a common input for receiving the input signal and a common output for providing an amplified version of the input signal;
wherein at least one of the amplifier cells is operable in:
a controllable gain mode in which the amplifier cell provides an amplification gain to the input signal based on the gain control signal; and
a fixed gain mode in which the amplifier cell provides a fixed, non-zero amplification gain to the input signal.

2. The amplifier circuit portion of claim 1 comprising multiple amplifier cells that are operable in the controllable gain mode and the fixed gain mode.

3. The amplifier circuit portion of claim 1, operable in a plurality of different minimum gain configurations in which different combinations of amplifier cells operate in the fixed gain mode.

4. The amplifier circuit portion of claim 1, wherein at least one of the amplifier cells is operable in a disabled mode in which the amplifier cell does not provide any amplification gain to the input signal.

5. The amplifier circuit portion of claim 4, wherein the amplifier circuit portion is operable in a plurality of different maximum gain configurations in which different combinations of amplifier cells operate in the disabled mode.

6. The amplifier circuit portion of claim 4, wherein at least one of the amplifier cells is operable in the controllable gain mode, the fixed gain mode and the disabled mode.

7. The amplifier circuit portion of claim 6, wherein all of the amplifier cells are operable in the controllable gain mode, the fixed gain mode and the disabled mode.

8. The amplifier circuit portion of claim 1, wherein the amplifier circuit portion is operable in a plurality of different sensitivity configurations in which different combinations of amplifier cells operate in the controllable gain mode and the fixed gain mode and optionally the disabled mode.

9. The amplifier circuit portion of claim 1, wherein one or more of the amplifier cells comprises a gain transistor and a switch transistor connected in series between a voltage rail and the common output, wherein gate of the gain transistor is connected to the common input and the operation of the amplifier cell is controlled by controlling a gate voltage of the switch transistor.

10. The amplifier circuit portion of claim 9, wherein an amplifier cell is operated in the fixed gain mode by fixing the gate voltage of the switch transistor to a fixed voltage above a threshold voltage.

11. The amplifier circuit portion of claim 9, wherein an amplifier cell is operated in the controllable gain mode by varying the gate voltage of its switch transistor according to the gain control signal.

12. The amplifier circuit portion of claim 9, wherein one or more of the amplifier cells comprises an inverter comprising:
an input connected to the enable signal;
an output connected to the gate voltage of the switch transistor; and
a supply voltage selected to be a fixed voltage or a variable voltage that is based on the gain control signal.

13. The amplifier circuit portion of claim 12, wherein the supply voltage is selected to be a fixed voltage or a variable voltage that is based on the gain control signal by a control enable signal for the respective amplifier cell.

14. The amplifier circuit portion of claim 1, wherein two or more of the amplifier cells have different sizes.

15. The amplifier circuit portion of claim 1, comprising a power amplifier for a radio transmitter device.

16. A device comprising a control circuit portion and the amplifier circuit portion of claim 1, wherein the control circuit portion is arranged to generate the gain control signal.

17. The device of claim 16, wherein the control circuit portion is arranged to configure the amplifier circuit portion.

18. The device of claim 16, wherein the control circuit portion is arranged to provide the input signal to the amplifier circuit portion.

19. The device of claim 16, wherein the device is a radio transmitter device arranged to transmit the amplified version of the input signal provided by the amplifier circuit portion as a radio signal.

20. The device of claim 19, arranged to sense a transmission power of the transmitted radio signal, wherein the control circuit portion is arranged to generate the gain control signal based on a sensed transmission power.
